(19) United States
(12) Patent Application Publication
(10) Pub. No.: US 2014/0292101 A1
(43) Pub. Date: Oct. 2, 2014

(54) SELECTIVE SHIELDING FOR PORTABLE HEATING APPLICATIONS

(71) Applicant: Access Business Group International LLC, Ada, MI (US)

(72) Inventors: David W. Baarman, Fennville, MI (US); Benjamin C. Moes, Wyoming, MI (US); Roy M. Taylor, JR., Rockford, MI (US)

(21) Appl. No.: 14/355,223

(22) PCT Filed: Dec. 6, 2012
(86) PCT No.: PCT/US2012/068059

§ 371 Date: Apr. 30, 2014

Related U.S. Application Data
(60) Provisional application No. 61/567,224, filed on Dec. 6, 2011.

(51) Int. Cl. H02J 5/00; H05K 9/00

(52) U.S. Cl. CPC H02J 5/005; H05K 9/00
USPC 307/104

(57) ABSTRACT

A wireless power supply and a portable heating device are provided. The wireless power supply includes an electromagnetic shield and the portable heating device includes a magnetic field source. Placement of the magnetic field source proximate the electromagnetic shield can create a local flux window in the electromagnetic shield. The transfer of electromagnetic flux through the local flux window energizes the portable heating device at various locations along the wireless power supply. The effectiveness of the electromagnetic shield is generally maintained away from the flux window, and the electromagnetic shield reduces stray flux that might otherwise damage nearby objects and/or reduce the efficiency of the wireless power supply.

### BACKGROUND OF THE INVENTION

The present invention relates to power supplies and more particularly to wireless power supplies capable of supplying power to portable heating devices.

Wireless power supplies can transfer electrical energy to portable devices without mechanical connection. A typical wireless power supply drives an alternating current through a primary coil to create a time-varying electromagnetic field. One or more portable devices can each include an inductive element. When the inductive element is placed in proximity to the electromagnetic field, the field induces a time-varying voltage in the inductive element, thereby transferring power from the wireless power supply to the portable device.

Wireless power supplies have been proposed for a number of applications, including applications involving portable heating devices. As the name suggests, portable heating devices differ apart from other portable devices in that a substantial portion of the power induced in the inductive element is directly or indirectly converted to heat. In the case of a clothes iron, for example, a substantial portion of the power received by the portable heating device is converted to heat in the iron's soleplate. That is, eddy currents are induced in the soleplate as a direct result of the electromagnetic field and generate heat at a rate proportional to the soleplate's electrical resistance.

In many instances it can be desirable to provide power to the portable heating device across multiple positions with respect to the primary coil. For example, a primary coil array can provide power to the cordless clothes iron at multiple locations along the ironing board. However, the primary coil array can generate a magnetic field directed only partially toward the inductive element, and away from the inductive element in equal or greater measure. As a result, stray electromagnetic field lines can cause undesirable heating in nearby metal objects, while also reducing the efficiency of the wireless power supply.

Accordingly, there remains a continued need for an improved wireless power supply to provide power to one or more portable heating devices. In addition, there remains a continued need for a low-cost wireless power supply to provide power to one or more portable heating devices across multiple positions relative to the primary coil while minimizing stray electromagnetic emissions that might otherwise impede efficient operation of the wireless power supply and potentially harm nearby objects.

### SUMMARY OF THE INVENTION

The present invention provides a wireless power supply system including a wireless power supply and a portable heating device. The wireless power supply includes an electromagnetic shield and the portable heating device includes a magnetic field source. Placement of the magnetic field source proximate the electromagnetic shield can create a local “flux window” in the electromagnetic shield. The resulting transfer of electromagnetic flux through the local flux window energizes the portable heating device, and stray electromagnetic field lines are reduced at other regions of the electromagnetic shield.

In one embodiment, the wireless power supply can include one or more primary coils and a power transfer surface adapted to supportably receive the portable heating device. The electromagnetic shield can be interposed between the one or more primary coils and the power transfer surface to reduce the effect of the electromagnetic flux outside of the wireless power supply. Optionally, the electromagnetic shield is a flux guide and concentrates the electromagnetic field lines within the electromagnetic shield.

In another embodiment, the wireless power supply includes power supply circuitry to drive the one or more primary coils with a time-varying current or voltage. The power supply circuitry can include a controller to vary a characteristic of power in the one or more primary coils. For example, the controller can be responsive to changes in the current, voltage or phase in the one or more primary coils. Alternatively, or in addition, the controller can be responsive to active or passive communications from the portable heating device.

In still another embodiment, the portable heating device includes a heating element that is directly or indirectly energized by the wireless power supply. For example, the heating element can include a conductive ferromagnetic material. When exposed to a time-varying electromagnetic field, eddy currents are induced in the material, and the resistance of the material dissipates energy in the form of heat. Also by example, the heating element can increase in temperature when subject to a suitable electrical current from a power source within the portable heating device. For example, a battery within the device or a rectified current from a secondary coil can power a heating element. In these configurations, the ferromagnetic material and/or the secondary coil can form an electromagnetic coupling with the primary coil through the localized flux window, providing energy to the heating element either directly from the primary coil through coupling, or indirectly by powering the secondary coil, or both.

In even another embodiment, the magnetic field source includes any device or material adapted to generate a persistent magnetic field, including for example a permanent magnet or an electromagnet. The magnetic field source can include multiple permanent magnets and/or multiple electromagnets to create flux windows of various sizes and shapes. For example, multiple permanent magnets and/or multiple electromagnets can be positioned radially outward of the heating element, or adjacent a major surface of the heating element. The portable heating device optionally includes a permanently magnetized conductive material that functions as both the magnetic field source and the heating element.

In yet another embodiment, the wireless power supply includes a primary coil array and an electromagnetic shield contained within an ironing board, and the portable heating device includes a heating element and a magnetic field source contained within a cordless clothes iron. The electromagnetic shield can encompass at least a substantial portion of the primary coil array to reduce the emission of stray electromagnetic field lines from the ironing board. As the user runs the cordless iron along the ironing board, a localized flux window moves in real time with the cordless iron. As a result, the heating element receives wireless power through the localized flux window, and the effectiveness of the electromagnetic shield is maintained elsewhere along the ironing board. Other portable heating devices can include curling irons, hair straighteners, heating pads, heated beverage containers and items of cookware.

In yet another embodiment, a wireless power receiver using electromagnets to saturate the interposed electromagnetic shield can control the amount of power received by adjusting the intensity of the induced DC magnetic field, thus adjusting the saturation level of the interposed magnetic shield. As a result, the transmitter can provide a more constant voltage/current and reduce reliance on communication between the transmitter and receiver. If the receiver is using multiple electromagnets spaced along the bottom of the device, the receiver can adjust the temperature of multiple points within the receiver, controlling where the device is heated.

In yet another embodiment, the portable heating device includes a magnetic field source including a specifically tuned Curie temperature (T_{c}). In this embodiment, the magnetic field source can saturate the interposed electromagnetic shield to allow inductive power transfer to the portable heating device. As the heating element is heated, the magnetic field source is also heated. As the temperature of the magnetic field source approaches T_{c}, its magnetic field strength decreases. This reduces the saturation of the electromagnetic shield, reducing the amount of power transferred to the portable heating device. In this embodiment, equilibrium can be reached where the magnetic field source is heated to a temperature less than T_{c}. If the wireless power supply heats the magnetic field source to T_{c}, the interposed electromagnetic shield is no longer saturated, and transfer of wireless power therethrough is stopped or slowed. The magnetic field source can be formed by combining a soft magnetic material such as iron with a resin, and curing the mixture in the presence of a magnetic field, creating a weak magnet. As the weak magnet is heated once again, the molecules lose their combined magnetic dipole moment as they near T_{c}.

In yet another embodiment, a wireless power receiver includes an electromagnetic shield that can be saturated to open an aperture allowing magnetic flux to pass through to a secondary coil. In this embodiment, the wireless power receiver controls when the shield is saturated (and to what level) using an electromagnet, or a wireless power supply may use a permanent magnet or an electromagnet to saturate the shield. This feature allows the wireless power circuitry in the receiver to be protected when the electromagnetic field is strong enough to damage the wireless power circuitry. For example, the wireless power receiver may be constructed to handle small amounts of power and communication. If such a receiver is placed next to a high-power wireless power supply capable of providing large amounts of magnetic flux energy, the electromagnetic field may damage the power circuitry in the receiver. To prevent this, the receiver may saturate the shield on both the remote device and the transmitter in the area of the low power coil and circuitry, begin communications and provide information about the portable device and its power requirements, then remove the DC magnetic bias in the area of the secondary coil. The system then saturates the shielding in the area between the area of the receiver requiring high power and the wireless power supply. Thus, the wireless power receiver can accept high power amounts in one area while protecting the low power areas. In this embodiment, the transmitter will typically provide high power for a period of time, and then reduce the power to allow the receiver to provide communications and power control. Additionally, the material may be heated until it reaches its Curie temperature, resulting in a saturation of the material (its relative permeability approaches ambient space). Once saturation is reached, the material may be cooled back below its Curie temperature using a heatsink or a peltier junction.

These and other advantages and features of the present invention will be more fully understood and appreciated in view of the description of the current embodiments and the drawings.

### BRIEF DESCRIPTION OF THE DRAWINGS

FIG. 1 is a circuit diagram of a wireless power supply system in accordance with an embodiment of the present invention.

FIG. 2 is a circuit diagram of the wireless power supply system of FIG. 1 including an internal battery and a secondary circuit.

FIG. 3 is a circuit diagram of the wireless power supply system of FIG. 2 including a heating element electrically coupled to the secondary circuit.

FIG. 4 is a schematic diagram of a wireless power supply system including a cordless clothes iron and an ironing board.

FIG. 5 includes schematic diagrams of primary coil configurations for the ironing board of FIG. 4.

FIG. 6 is a side elevational view of the wireless power supply of FIG. 4 illustrating the cordless clothes iron seated in a charging cradle.

FIG. 7 is a bottom view of the cordless iron of FIG. 4 illustrating a heating element and multiple permanent magnets.

FIG. 8 is a bottom view of the cordless iron of FIG. 4 illustrating a magnetized heating element.

FIG. 9 is a flow diagram illustrating operation of the wireless power supply system of FIG. 4.

FIG. 10 is a circuit diagram of a receiver wherein the heating element is also powered by direct current from the secondary.

FIG. 11 is a flow diagram of a system that utilizes the Curie point of the magnetized material to control the temperature of the receiver heating element.

FIG. 12 is a graph indicating the heating power of a portable heating device.

FIG. 13 is a graph indicating the heating power of a portable heating device including a battery having a capped output.

FIG. 14 is a circuit diagram of a portable heating device including multiple magnetic elements adapted to saturate discrete portions of an electromagnetic shield.

FIG. 15 is a circuit diagram of the portable heating device of FIG. 14 including a shielding element proximate the secondary coil.

FIG. 16 is a flow diagram illustrating operation of the portable heating device of FIG. 14.

FIG. 17 is a first schematic diagram illustrating operation of a portable heating device including a secondary shield and a heating element.

FIG. 18 is a second schematic diagram illustrating operation of a portable heating device including a secondary shield and a heating element.

FIG. 19 is a flow diagram illustrating a pre-heating sequence for a portable heating device.

FIG. 20 is a graph showing a change in coupling coefficient between stationary coils as an intermediate ferrite plate is heated to its currie temperature.

### DESCRIPTION OF THE CURRENT EMBODIMENTS

The current embodiments relate to systems and methods for providing a source of wireless power to a portable heating device. The systems generally include a wireless power supply having an electromagnetic shield and a portable heating device having a magnetic field source. Placement of the magnetic field source proximate the electromagnetic shield creates a localized flux window in the electromagnetic shield. The effectiveness of the electromagnetic shield is generally maintained apart from the flux window, and the electromagnetic shield reduces stray flux that might otherwise cause an undesired electromagnetic coupling with the wireless power supply.

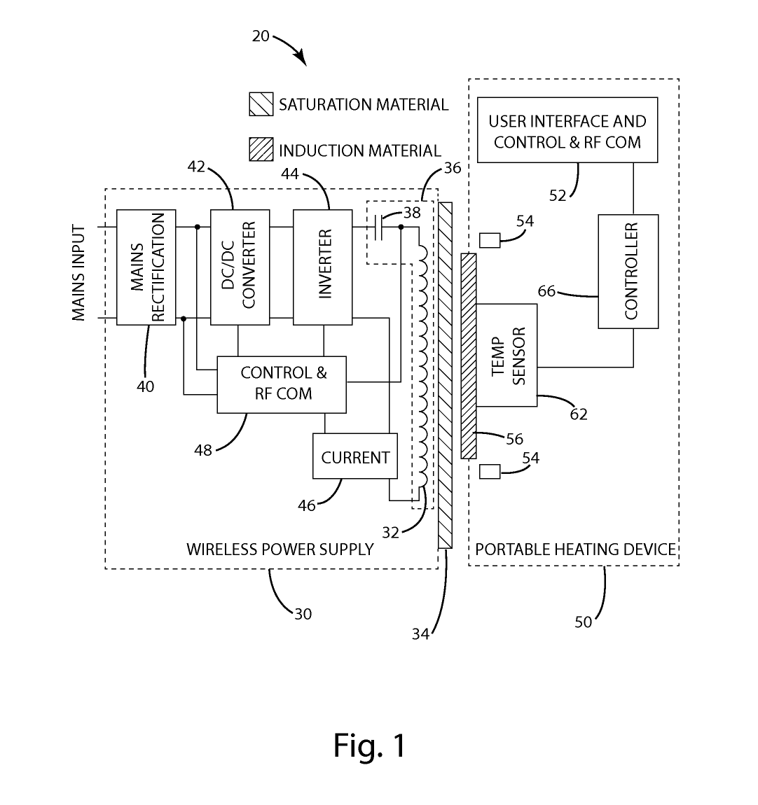

More specifically, and with reference to FIG. 1, a wireless power supply system in accordance with a first embodiment of the invention is shown and generally designated 20. The wireless power supply system 20 includes a wireless power supply 30 and a portable heating device 50. The wireless power supply 30 includes one or more primary coils 32 and an electromagnetic shield 34 to reduce electromagnetic coupling therethrough. The electromagnetic shield 34 can encompass all, substantially all, or only a portion of the one or more primary coils 32 to reduce the electromagnetic field external to the wireless power supply 30. The wireless power supply 30 can be adapted to supportably receive the portable heating device 50 while selectively generating a time-varying electromagnetic field from within the wireless power supply 30.

The primary coil or coils 32 can form part of a primary tank circuit 36. In the illustrated embodiment, the primary tank circuit 36 includes a series resonant capacitor 38, and the primary tank circuit 36 is positioned proximate to or subjacent the electromagnetic shield 34. The wireless power supply 30 can further include power supply circuitry to drive the primary tank circuit 36 with a time-varying current or voltage. For example, the power supply circuitry can include a mains rectifier 40, a DC to DC converter 42, an inverter 44 and a current sensor 46. The mains rectifier 40 can convert a mains voltage into a DC voltage, and can include a full bridge rectifier, a half bridge rectifier, or other rectifier having a DC output. The DC to DC converter 42 is electrically connected to the output of the mains rectifier 40 and provides a conditioned output to the inverter 44. The inverter 44 in turn generates a time-varying current or voltage in the primary tank circuit 36 under the control of a controller 48. The controller 48 can selectively vary one or more characteristics of power in the primary tank circuit 36 to improve the transfer of power from the wireless power supply 30 to the portable heating device 50. For example, the controller 48 can vary the operating frequency, duty cycle, pulse width, waveform, amplitude and/or phase in the primary tank circuit 36, as well as other parameters including the resonant frequency and/or the impedance of the primary tank circuit. In some embodiments the controller 48 is responsive to changes in a characteristic of power in the primary tank circuit 36, including for example current, voltage or phase. The controller 48 can additionally or alternatively be responsive to transmissions from a dedicated communications unit 52 associated with the portable heating device 50 as generally depicted in FIGS. 1-3.

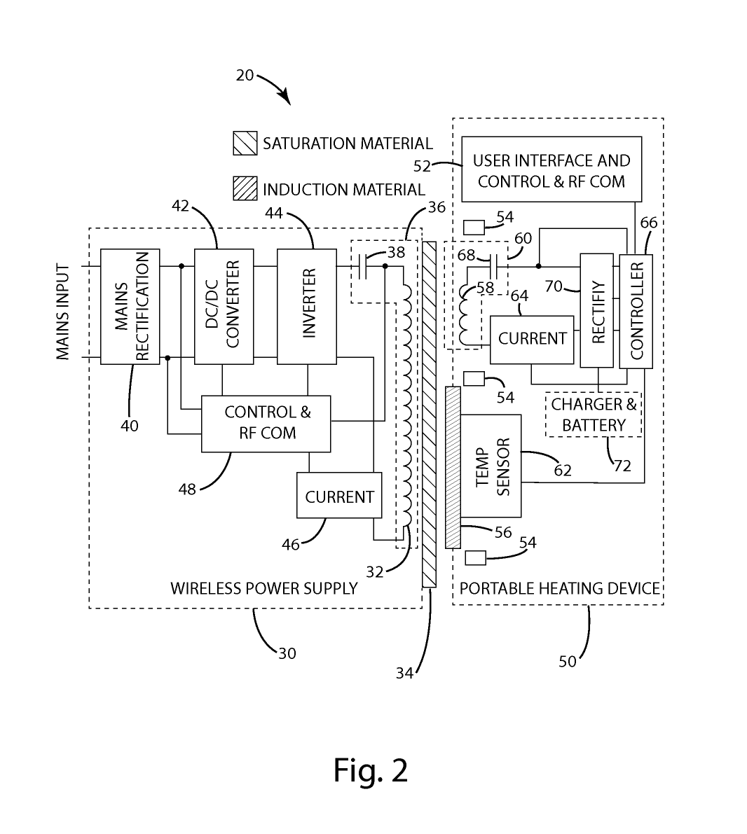

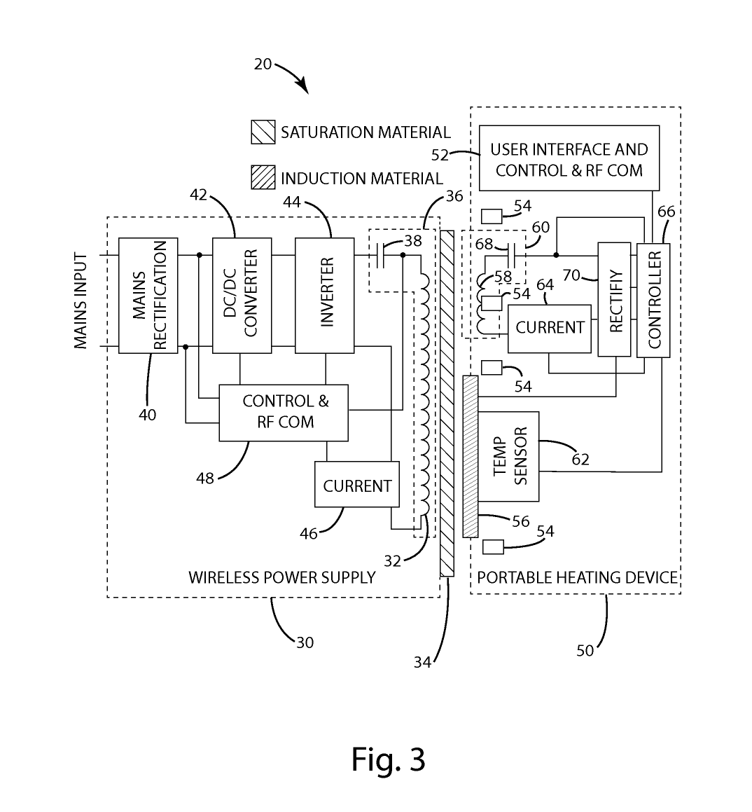

As noted above, the portable heating device 50 includes a magnetic field source 54 and a heating element 56 that is directly or indirectly energized in response to a time-varying electromagnetic field generated by the wireless power supply 30. The magnetic field source 54 can include any device adapted to generate a persistent magnetic field, including for example a permanent magnet or an electromagnet. Exemplary permanent magnets include single bonded NdFeB magnets (also known as a neodymium, NIB, rare earth, or Neo magnets), ferrite magnets, sintered NdFeB magnets, sintered SmCo magnets or Alnico magnets. The desired magnetic field source 54 can be selected to have a sufficient magnetic flux density, also referred to as the magnetic field strength, to generate a localized flux window in the electromagnetic shield 34. The magnetic field source 54 can be oriented within the portable heating device 50 to generate a flux window by magnetically saturating a localized portion of the electromagnetic shield 34. For example, the magnetic field source 54 can include multiple permanent magnets and/or electromagnets oriented such that a common magnetic pole is closest to the electromagnetic shield 34. The magnetic field source 54 can also include multiple permanent magnets and/or electromagnets to create flux windows of various sizes and shapes. As shown in FIG. 1, the magnetic field source 54 includes multiple permanent magnets positioned radially outward of the heating element 56. Alternatively, the magnetic field source 54 can be positioned adjacent a major surface of the heating element 56, including the major surface nearer to the electromagnetic shield 34 and/or the major surface opposite of the electromagnetic shield 34. As alternatively shown in FIGS. 2-3, the magnetic field source 54 can include magnets positioned radially outward of an optional secondary coil 58. In still other embodiments, the magnetic field source 54 can include a core magnet in alignment with the optional secondary coil 58, and can include one or more magnets seated within apertures or recesses in the heating element 56. As noted below in connection with FIG. 8, the magnetic field source 54 can also include a permanently magnetized conductive material that functions as a magnetic field source and a heating element.

The heating element 56 is directly or indirectly energized in response to the time-varying electromagnetic field or flux directed through the flux window in the electromagnetic shield 34. For example, FIGS. 1-2 illustrate a heating element 56 formed of a ferromagnetic material that increases in temperature when exposed to a time-varying electromagnetic field. By comparison, FIG. 3 illustrates a heating element 56 that increases in temperature when subject to a suitable current from a secondary circuit 60. The wireless power supply system 20 can also include feedback to vary the power output of the primary tank circuit 36, e.g., the electromagnetic field density through the flux window. As shown in FIG. 1 for example, the portable heating device 50 can include a temperature sensor 62 having an output based on the temperature of the heating element 56. As further optionally shown in FIGS. 2-3, the portable heating device 50 can include a current sensor 64 having an output based on the current induced in the secondary circuit 60. The portable heating device controller 66 can compare each sensor output against a threshold value and, if greater or lesser heating is desired, communicate a desired change in primary tank circuit output to the wireless power supply 30. Alternatively, this comparison can be performed at the wireless power supply controller 48. The portable heating device 50 can also utilize the electromagnetic flux from the wireless power supply 30 to power an internal battery and/or other internal electrical loads. As shown in FIGS. 2-3 for example, the secondary circuit 60 includes a secondary coil 58 and a series resonant capacitor 68. An optional rectifier 70 can convert the time-varying current induced in the secondary circuit 60 into a DC waveform to power a rechargeable battery 72, the internal communications unit 52, the controller 66 and/or other components of the portable heating device 50. In this regard, the wireless power supply 30 functions as a charging station in addition to its role as a source of power for the heating element 56.

The electromagnetic shield 34 can be formed of any material exhibiting a suitably high magnetic permeability (p). For example, the shielding material can exhibit a magnetic permeability at least ten times the magnetic permeability of free space, or μ/μ₀>10. The electromagnetic shield 34 can also be formed of a material exhibiting a suitably low resistance to magnetic saturation. For example, the shielding material can be readily saturated to the point that the localized permeability approaches that of free space in the presence of the magnetic field source 54. The electromagnetic shield 34 can also be formed of a material having a sufficiently low conductivity to minimize the accumulation of eddy currents therein. Suitable shielding materials can include soft metallic materials such as sheet steel, silicon steel, cast steel, tungsten steel, magnet steel, cast iron, nickel, cobalt and magnetite. Other materials can include a flexible composite ferrite, such as FLEXIELD IRJ09, and/or a pre-fractured ferrite, such as FLEXIELD IBF20, both available by TDK Corporation of Garden City, N.Y. In addition, the thickness of the shielding material may also play a role in the amount of the magnetic field required to saturate the shield. For example, a thinner shield will typically be more easily saturated than a thicker shield. The electromagnetic shield of the present invention may sometimes be referred to by names that reflect its ability to function as a flow path for electromagnetic field lines, such as a flux guide, a flux concentrator or a magnetic flux concentrator.

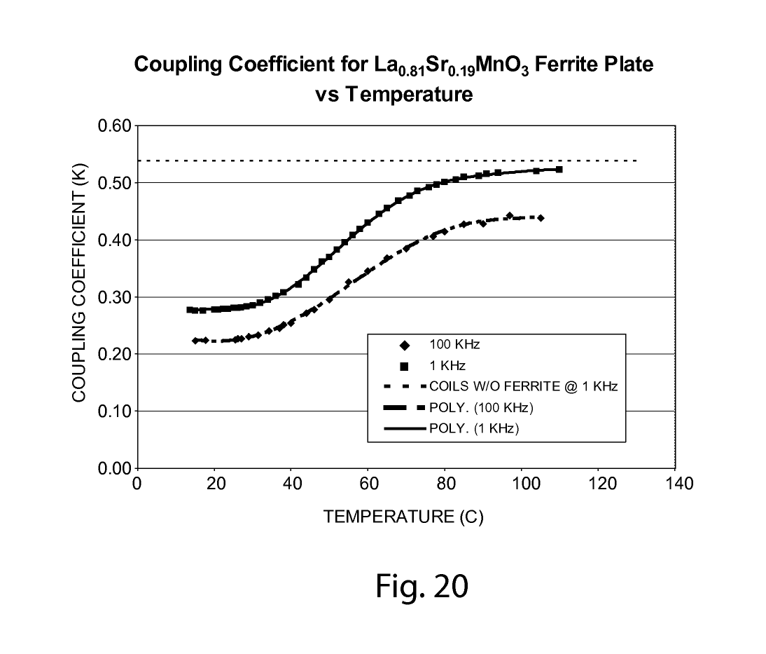

The heating element 56 can also be preheated. For example, an energy storage element can be used to pre-heat the heating element 56, and/or a charging station 106 can be used to pre-heat the heating element 56. This may be accomplished using an inductive heating element, or by passing current directly through the heating element from a battery or other power source. Once the heating element 56 has reached a sufficient pre-heat temperature, as optionally measured by a temperature sensor 62, the portable heating device 50 can generate an alert, for example an audible alert, a luminescent alert, or a mechanical vibration. The remote device is then placed atop a power transfer surface. Heat from the heating element 56 heats the electromagnetic shield 34 and reduces its electromagnetic permeability in the region of a localized flux window. As the electromagnetic permeability decreases, the coupling between primary coil 32 and the portable heating device 50 increases. This increase in coupling is depicted in FIG. 20 for an electromagnetic shield formed of La_{0.91}Sr_{0.19}MnO₃ combined with Epon SU-8 and Epikure P-104 resins. In particular, a shielding temperature increase of 60° C. resulted in a corresponding increase in coupling coefficient of 0.20 (0.22 to 0.42) for a 100 KHz driving frequency and 0.24 (0.28 to 0.52) for a 1 KHz driving frequency.

To reiterate, the localized flux window can be generated by directly or indirectly heating the electromagnetic shield, independent of whether the electromagnetic shield is also saturated with a nearby magnet. Heating of the electromagnetic shield can decrease its effectiveness as a flux guide, thereby increasing the magnetic flux through the electromagnetic shield. A pre-heated article in the vicinity of the electromagnetic field, and opposite of the primary coil, can receive wireless power more readily than a room-temperature article. In this regard, the electromagnetic coupling between pre-heated article and the primary coil is likely greater than the electro-magnetic coupling between the room-temperature article and the primary coil. This difference in coupling coefficients is functionally a safeguard against inadvertently energizing a nearby room-temperature article. In addition, as the pre-heated article is positioned over or moved along the wireless power supply power transfer surface, the electromagnetic coupling maintains the elevated temperature of the heating element 56, which in turn maintains the elevated temperature of the electromagnetic shield.

The electromagnetic shield 56 may optionally be cooled with a heat sink or a peltier junction to cool the shielding material below T_{c}, and optionally to room temperature, optionally when the portable heating device 50 is no longer on the surface of the wireless power supply 30. Although the electromagnetic shield 34 prevents much of the electromagnetic flux from passing through the power transfer surface, some flux may still pass through to the portable heating device 50. This field may be used by the portable heating device 50 to heat the heating element 56 substantially as set forth above.

In some embodiments it can be desirable to incorporate an electromagnetic shield 34 into the portable heating device 50. For example, it can be desirable to provide a portable heating device 50 that is generally shielded from certain external electromagnetic fields. In this configuration, the wireless power supply 30 will generally include a magnetic field source, such as one or more permanent magnets or electromagnets. When the portable heating device 50 is placed adjacent to the wireless power supply 30, the magnetic field source will generate a localized flux window in the electromagnetic shield. Electromagnetic field lines from within the wireless power supply 30 can more readily penetrate the electromagnetic shield at the localized flux window to provide power to the portable heating device 50 in the manner set forth above.

To reiterate, the electromagnetic shield 34 can reduce the effect of electromagnetic field lines originating within the wireless power supply on external objects or devices. The electromagnetic shield 34 can also be selectively saturated by the magnetic field source 54. In a non-saturated state, the shield 34 has a high magnetic permeability relative to free space, and therefore draws much of the electromagnetic field into itself. In a saturated state, the shield 34 has a greatly reduced magnetic permeability relative to free space, and therefore enhances the electromagnetic coupling of the primary coil 32 with external objects or devices. It should be noted that “saturation” as used herein refers to substantial saturation and is not limited to complete saturation.

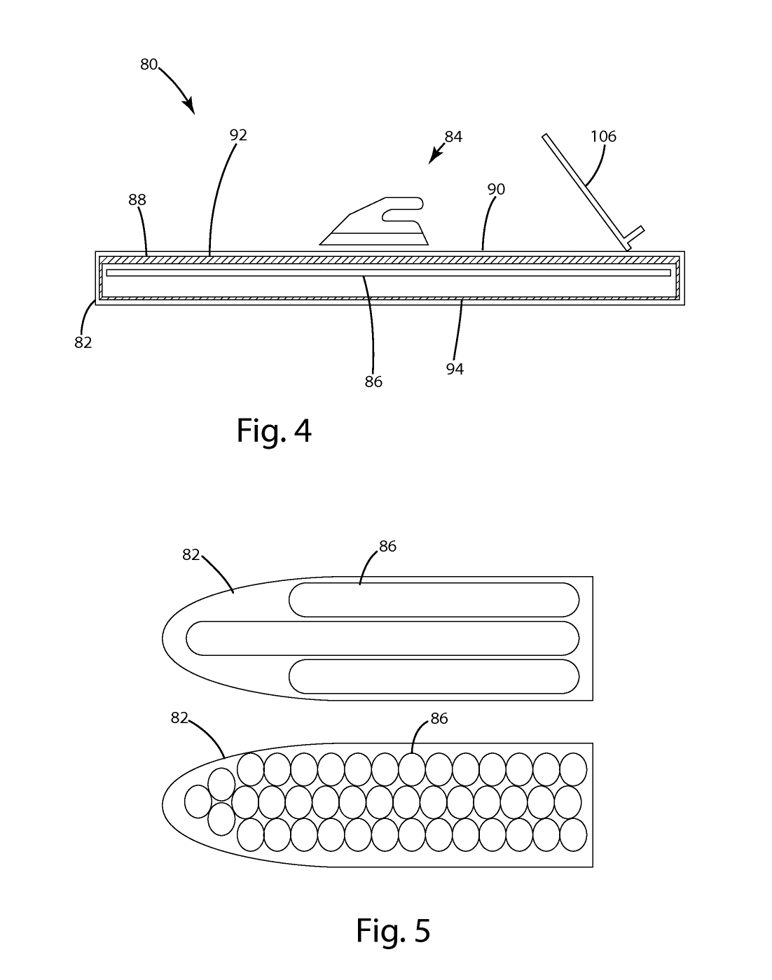

Embodiments of the invention can be utilized in connection with a wide variety of portable heating devices 50, including for example cordless clothes irons, curling irons, hair straighteners, heating pads, heated beverage containers and cookware. In these embodiments, the wireless power supply 30 can be self-contained within any of a variety of surfaces, including for example ironing boards, wall-mounted holding racks, bathroom or kitchen countertops, stovetops and portable charging pads. As illustrated in FIGS. 4-9, for example, a wireless power supply system in accordance with another embodiment is illustrated and generally designated 80. The wireless power supply system 80 includes an ironing board 82 and a cordless clothes iron 84. The ironing board 82 includes one or more primary coils 86 and an electromagnetic shield 88. The configuration of the one or more primary coils 86 can vary from application to application as desired. As shown in FIG. 5, for example, the one or more primary coils 86 encompass an area generally coextensive with the ironing board working surface 90. Optionally, an array of primary coils 86 can include three elongate or oval-shaped primary coils in a side-by-side relationship. Further optionally, an array of primary coils 86 can include a series of equally-sized coils in non-overlapping arrangement. Other configurations can also be utilized, including overlapping coils, counter-wound coils, and coils of various sizes, shapes, orientations, gages, spacing, cores and turns of wire.

Referring again to FIG. 4, the electromagnetic shield 88 encompasses at least a substantial portion of the primary coils 86 to prevent or reduce the emission of stray electromagnetic field lines from the ironing board 82. For example, the electromagnetic shield 88 can include an upper layer 92 having a first thickness greater than the thickness of the lower layer 94. The lower layer 94 can be configured to function as an effective shield in instances where a magnetic field source generates a flux window in the upper layer 92. For example, the lower layer 94 can be made thicker than the upper layer 92, and/or can be formed from a different material, including pressed iron for example. As also shown in FIG. 4, the ironing board 82 can further include a charging cradle 106 to supportably receive the iron 84 during periods of non-use while providing a source of wireless power to preheat the cordless iron 84. As explained below, the charging cradle 106 can optionally include one or more primary coils for generating a time varying magnetic field in response to a manual activation of the cordless iron 84.

The cordless iron 84 includes a heating element 96 and a magnetic field source 98. The magnetic field source 98 optionally includes multiple magnets embedded within the heating surface 96. As shown in FIG. 7 for example, the magnetic field source 98 can include eight equidistant permanent magnets received within eight corresponding apertures in the heating surface 96. The cordless iron 84 can alternatively include a permanently magnetized conductive material forming both the magnetic field source 98 and the heating element 96. In this configuration as shown in FIG. 8, the magnetic-heating element 104 is formed of a hard magnetic material, for example alnico, ferrite and/or other ferromagnetic alloys. In some embodiments a non-stick surface, for example TEFLON® by DuPont of Wilmington, Del., is positioned adjacent an exterior facing surface of the heating element 96. In these embodiments, the heating element 96 and the non-stick surface cooperate to form the iron's soleplate. The cordless iron 84 can also include an internal storage battery, an accelerometer, a dedicated communications unit, a temperature sensor and a controller substantially as set forth above in connection with FIG. 2.

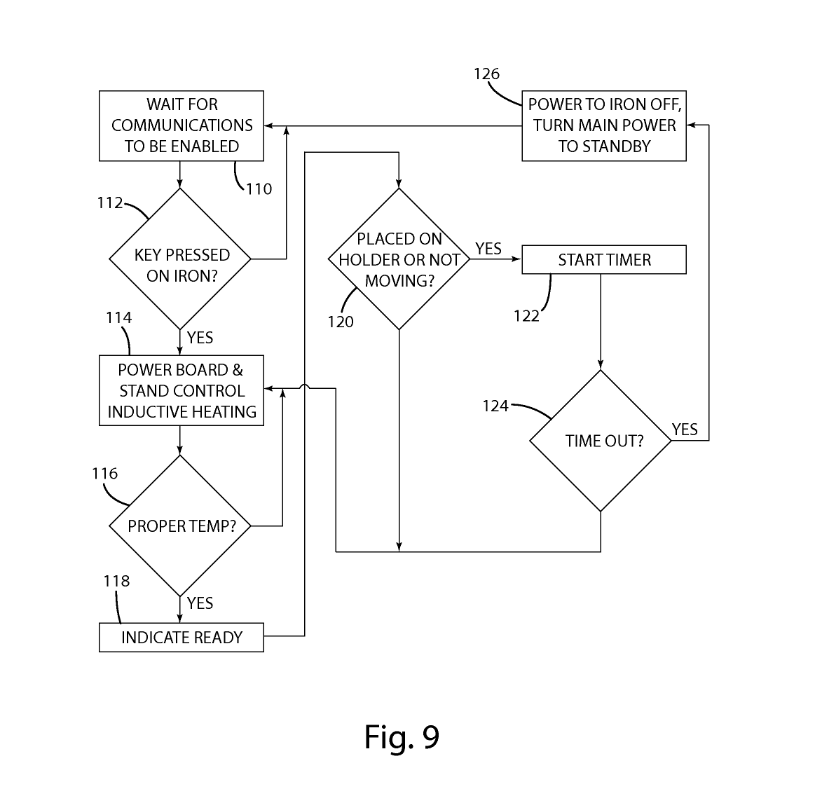

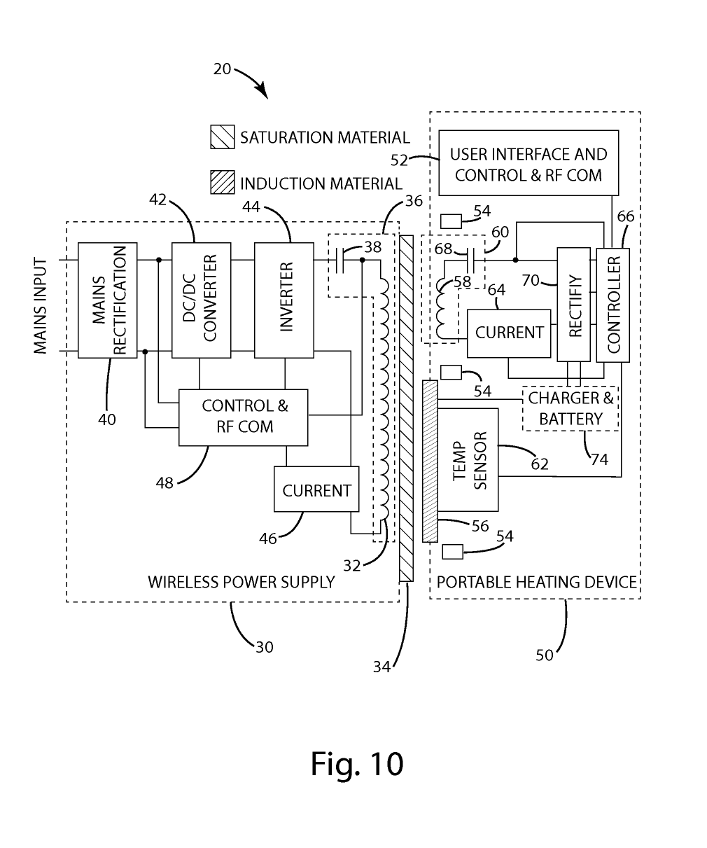

Operation of the cordless clothes iron can be understood with reference to FIG. 9. Between periods of use, the cordless iron is generally seated in the stowed position on the charging cradle. Optionally, the presence of the cordless iron in the charging cradle can be confirmed using a pressure switch in the charging cradle. At step 110, the cordless iron attempts to establish a communication link with the wireless power supply contained within the ironing board. With the communications link established, the wireless power supply determines at decision step 112 whether the cordless iron has been manually activated for use. If at decision step 112 the cordless iron has not been recently activated, the wireless power supply returns to step 110. If however the cordless iron has been manually activated sense last polled, the wireless power supply drives each primary coil in the ironing board with a time varying current at step 114. As a result, the wireless power supply generates an electromagnetic field from within or behind the electromagnetic shield at step 114. If the cordless iron is instead positioned in the charging cradle, only the primary coils contained therein can be energized. At decision step 116 the wireless power supply determines whether the soleplate is sufficiently pre-heated for use. For example, the wireless power supply can receive an active or passive communication from the cordless iron representative of the temperature of the soleplate. The communication can originate from the dedicated communications unit 52, the secondary coil 58 or any other suitable device associated with the cordless iron. If at decision step 116 the soleplate is determined to be outside (e.g., typically below) a desired temperature range, the pre-heat process continues at step 114. If however the soleplate is sufficiently pre-heated, the cordless iron provides a visual or audible indication that the iron is ready for use, as shown at step 118.

At decision step 120, the wireless power supply determines whether the cordless iron is stationary. This can indicate the cordless iron is seated within the charging cradle or otherwise stationary along the ironing board working surface, despite the cordless iron being ready for use. If at decision step 120 the cordless iron is determined not to be stationary—optionally with the aid of one or more accelerometers—the wireless power supply maintains the soleplate at the desired temperature at step 114 with feedback from step 116. As the user moves the cordless iron over the ironing board, the magnetic field source creates a localized flux window in the electromagnetic shield. The resulting transfer of electromagnetic flux through the local flux window directly or indirectly heats the soleplate, while maintaining reduced stray electromagnetic emissions at other regions along the ironing board working surface. If however the cordless iron is determined at step 120 to be stationary, an internal timer initiates a standby period at step 122 in which the cordless iron remains on and heated. At decision step 124 and after the standby period, the cordless iron is deactivated at step 126 or remains on at step 114, optionally in response to detected movement of the cordless iron. If deactivated, the above process repeats itself at step 110.

The cordless iron can therefore receive wireless power through a localized flux window that moves in real time with the cordless iron. As the user runs the cordless iron along the ironing board working surface, the flux window essentially shadows the cordless iron at all locations along the ironing board. Because the flux window is localized, the effectiveness of the electromagnetic shield is maintained elsewhere along the ironing board. This can be of notable concern in instances where parasitic metal objects might otherwise intersect with a leaked electromagnetic field. Instead, electromagnetic losses are minimized, and the risk of inadvertently heating nearby metallic objects is also minimized.

In another embodiment as shown in FIG. 10, the heating element 56 is indirectly energized by the wireless power supply 30. In this embodiment, a time-varying current induced in the secondary coil 58 is converted to a DC waveform by the rectifier 70. The rectifier 70 provides a DC output to an internal power supply 74, for example a rechargeable battery, which in turn provides a source of electrical power for the heating element 56. In this configuration, the internal power supply 74 is electrically connected between the rectifier 70 and the heating element 56. The wireless power supply system 20 of FIG. 10 is otherwise substantially identical in structure and function to the wireless power supply system 20 of FIG. 3. The internal power supply 74 can additionally power other internal loads, including the aforementioned accelerometer, communications unit 52, temperature sensor 62 and a controller 66, for example.

The portable heating device 50 can also control the amount of power transferred by adjusting the saturation level of the interposed electromagnetic shield 34. When the portable heating device 50 utilizes magnetic field sources 54 at least partially composed of electromagnets to provide a DC magnetic field to saturate the electromagnetic shielding 34, the secondary controller 66 can adjust the amount of current flowing through the electromagnets 54, or the number of turns of the electromagnet. By reducing the current or number of turns, the magnetic flux density of the electromagnets 54 are reduced, reducing the saturation level of the electromagnetic shield 34. This in turn reduces the amount of field coupled into the portable heating device 50.

Additionally, if the portable heating device 50 utilizes magnetic field sources 54 at least partially composed of permanent magnetic materials, the controller 66 may utilize the Curie temperature of the magnetic materials to control the temperature of the heating element 56. For example, if the temperature of the heating element 56 nears the Curie temperature of the nearby magnetized material 54, the magnetized material begins to lose some of its magnetism. This reduces the field strength of the magnet, reducing the saturation level of the electromagnetic shield 34. If the saturation level of the electromagnetic shield 34 is reduced enough, the permeability of the shield 34 begins to rise, reducing the amount of flux coupled into the portable heating device coil 58 and/or the induction material 56. If heat energy is drawn off from the portable heating device 50 at the same rate as it is added from the coupled energy, the portable heating device 50 will maintain an equilibrium temperature. If more heat energy is coupled into the portable heating device 50 than what is removed, the temperature will continue to increase, making the temperature of the magnetized material 54 rise closer to its Curie temperature, further reducing its magnetism. If the Curie temperature of the magnetized material 54 is reached, or if the amount of heat energy being removed from the portable heating device 50 is greater than what is being added, the portable heating device 50 will begin to cool.

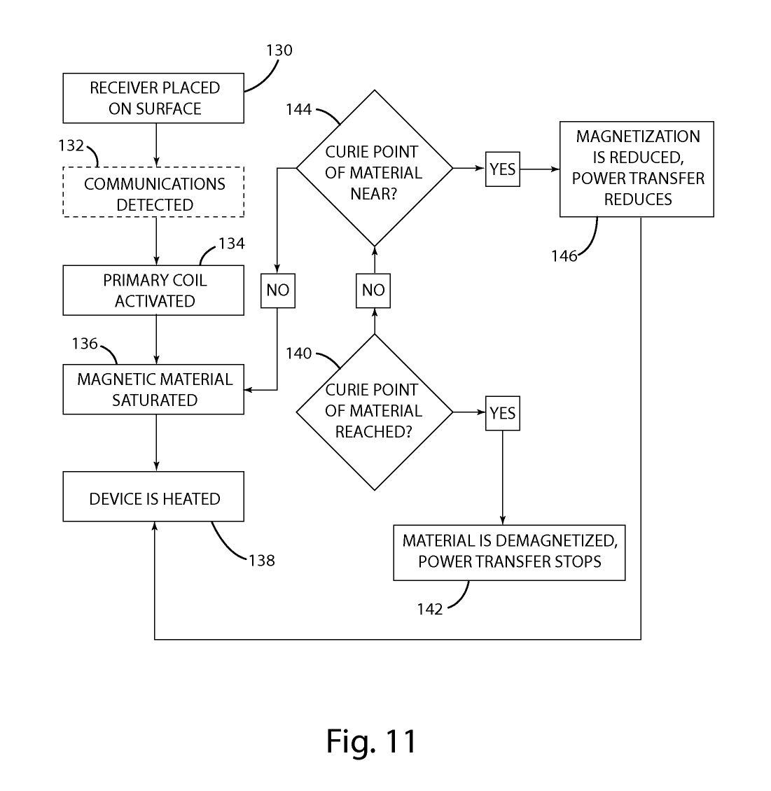

A method for controlling the transfer of power from the wireless power supply 30 to the portable heating device 50 is illustrated in FIG. 11. At step 130, the portable heating device 50 is placed on a power transfer surface 90. At step 132, the wireless power supply communications unit 48 detects passive or active communications from the portable heating device 50. For example, wireless communication by the portable heating device communications unit 52 can indicate the presence of the portable heating device 50 on the power transfer surface 90 as well as power demand information. At step 134, a time-varying operating current is generated in the primary tank circuit 36. The presence of the portable heating device 50 on the power transfer surface 90 generates a localized flux window through the shielding material 34. In particular, the presence of a static magnetic field from the magnetic elements 54 substantially saturates portions of the shielding layer 34 at step 136. The transfer of electromagnetic flux through these saturated portion(s) operates to directly energize the heating element at step 138 substantially as set forth above in connection with FIG. 1. At decision step 140, the magnetic elements 54 have or have not heated to their Curie point. If yes, the magnetic elements 54 shed much or most of their ability to saturate the shielding layer 34 at step 142, and power transfer through the shielding material is substantially reduced. Because this effect is reversible, the magnetic elements 54 regain the ability to saturate the shielding layer 34 if and when they cool to below their Curie point. If the magnetic elements 54 have not heated to their Curie point, the wireless power supply 30 continues its transfer of wireless power through the flux window. At decision step 144, the magnetic elements 54 either approach their Curie point or remain sufficiently below their Currie point. If the magnetic elements are approaching their Curie point, typically though not necessarily in response to heating of the nearby heating element 56, magnetization is reduced at step 146, and the portable heating device 50 is energized with less flux through a reduced flux window. If the magnetic elements are not approaching their Curie point at step 144, the electromagnetic shield 34 remains locally saturated. In this regard, the wireless power supply 30 and portable heating device 50 provide a stable system in which power transfer through the electromagnetic shielding layer 34 asymptotically approaches, but does not exceed, a point at which the magnetic elements 54 heat to above their Curie point.

The wireless power supply 30 can also be utilized to directly and indirectly power a heating element. Referring again to FIG. 10, the wireless power supply 30 includes a shielding layer 34 that encompasses all, substantially all, or only a portion of the one or more primary coils 32 to reduce the electromagnetic field external to the wireless power supply 30. The portable heating device 50 includes magnetic elements 54 adapted to generate a persistent magnetic field, including for example multiple permanent magnets. The permanent magnets 54 are disposed radially outward of a heating element 56 and radially outward of a secondary coil 58. Application of a time varying current through the primary coil 32 energizes both the ferromagnetic heating element 56 and the secondary coil 58 through localized flux windows in the shielding layer 34. Eddy currents induced in heating element 56 generate heat, and electrical current induced in the secondary coil 58 powers a load, for example a rechargeable battery 74, to indirectly heat the heating element 56. That is, the rechargeable battery 74 provides battery heating power to complement and in some instances replace the induction heating power of the heating element 56.

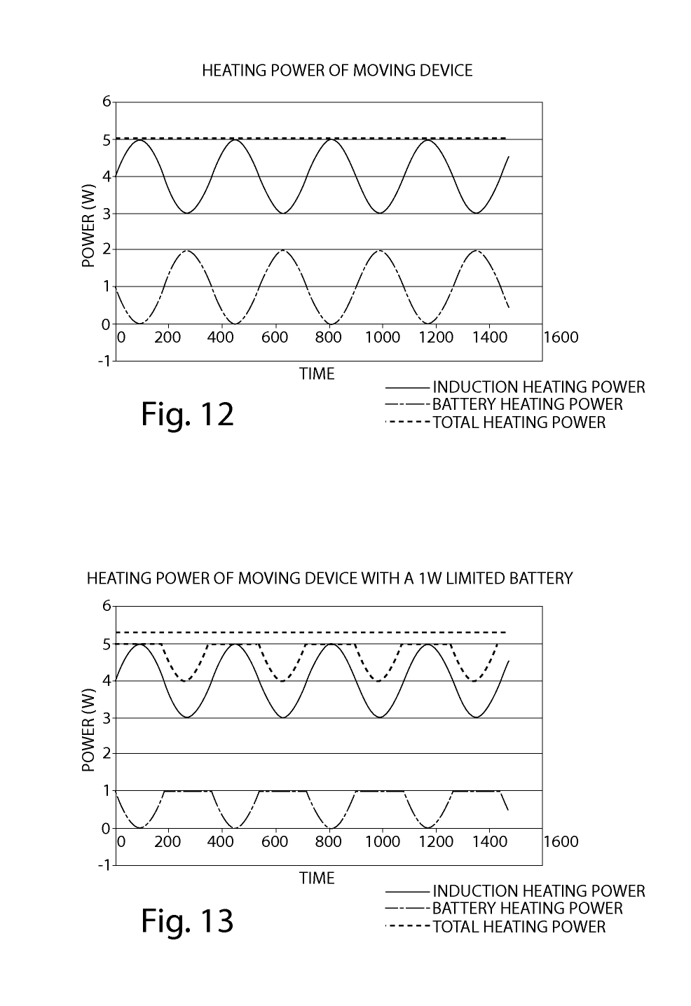

An example of this relationship is illustrated in FIGS. 12-13. As shown in FIG. 12, the induction heating power is represented by a repeating sinusoidal waveform centered at 4 Watts, and the battery heating power is represented by a repeating sinusoidal waveform centered at 1 Watt. The battery heating power lags the induction heating power by 180 degrees to achieve a combined heating power of 5 Watts. As alternatively shown in FIG. 13, the battery heating power can be represented by other than a repeating sinusoidal waveform. For example, the battery heating power is represented by a maximum-rated 1 Watt output with periodic sinusoidal variations to 0 Watts. The combined heating power is 5 Watts with periodic sinusoidal variations to 4 Watts. The combined heating power can increase or decrease depending on desired power settings on the portable heating device 50. For example, as a user indicates a desired decrease in total heating power, the battery heating power can likewise decrease to transition from the total heating power of FIG. 12 to the total heating power of FIG. 13.

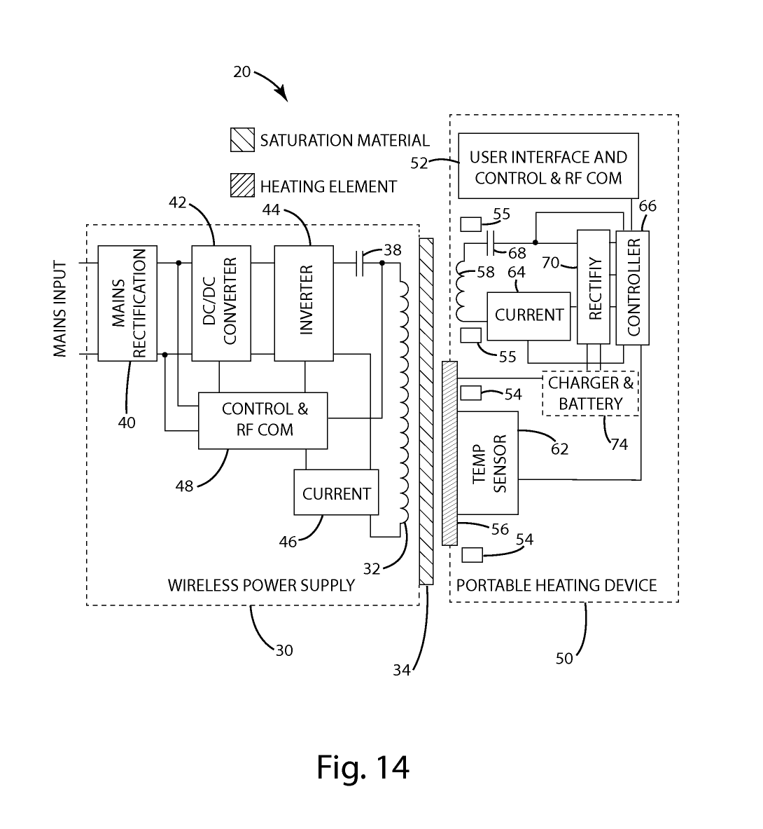

In another embodiment as shown in FIG. 14, the portable heating device 50 includes multiple magnetic elements 54, 55 adapted to selectively saturate discrete portions of a shielding material 34 to varying degrees and on an as-needed basis. The portable heating device 50 of FIG. 14 is structurally and functionally similar to the portable heating device of FIG. 10, and includes a first plurality of magnetic elements 54 proximate the heating element 56 and a second plurality of magnetic elements 55 proximate the secondary coil 58. The first and second plurality of magnetic elements 54, 55 include any device or material adapted to generate a persistent magnetic field with a controllable magnetic field strength. In the illustrated embodiment, the first and second plurality of magnetic elements 54, 55 are electromagnets. The magnetic field strength of each electromagnet is a function of (e.g., proportional to) the amount of current in the corresponding electromagnet. For example, the electromagnets 54, 55 can be driven with a suitable DC current from the rechargeable battery circuit 74 under the control of the controller 66. As the current in each electromagnet increases, the magnetic field strength also increases to generate a flux window or windows in the shielding layer 34.

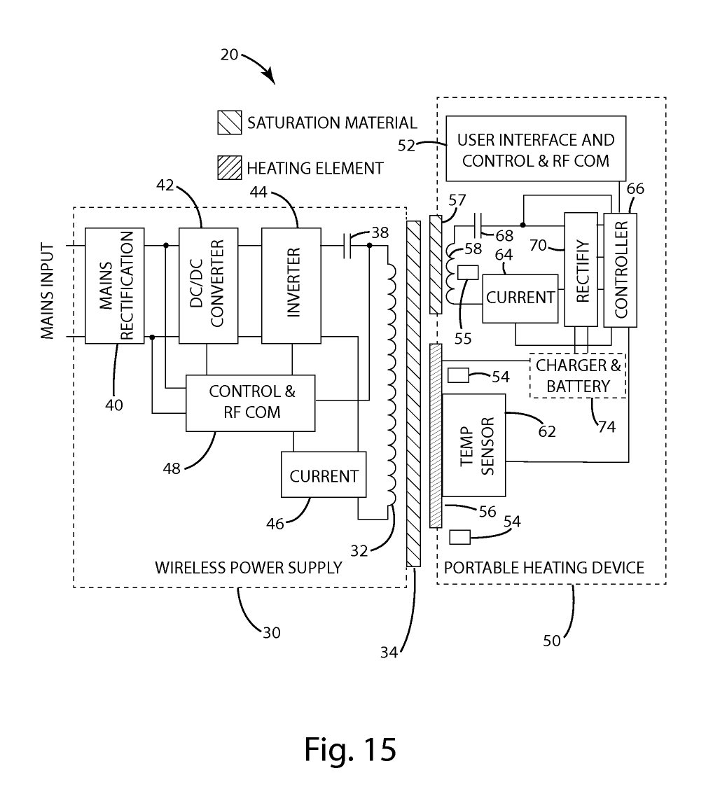

As optionally shown in FIG. 15, the portable heating device 50 can also include an added shielding layer 57 interposed between the secondary coil 58 and primary coil 32, particularly though not necessarily where the wireless power supply 30 does not include a shielding layer 34. The added shielding layer 57 can be formed of any material exhibiting a suitably high magnetic permeability and a suitably low resistance to magnetic saturation. In the illustrated embodiment, the added shielding layer 57 is formed of the same material as the primary shielding layer 34, while in other embodiments the shielding layers 34, 57 are formed of different materials. Optionally, a single electromagnet 55 is positioned proximate the added shielding layer 57 to selectively saturate the shielding layer 57. The added shielding layer 57 can be sized or positioned to shield other components of the portable heating device 50, including for example the internal communications unit 52 and an optional RF transceiver. The optional shielding layer 57 associated with the portable heating device 50 can be selected such that once the heating element 56 or the magnetic material 57 reaches its Curie temperature the shielding layer 57 will lose its permeability (its relative permeability will approach unity). Once this happens, the wireless power transmitter may detect a large change in inductance due to the reduction of the permeability of the shielding layer 57. The wireless power supply 30 may then reduce or stop the transfer of power to maintain the temperature of the heating element 56.

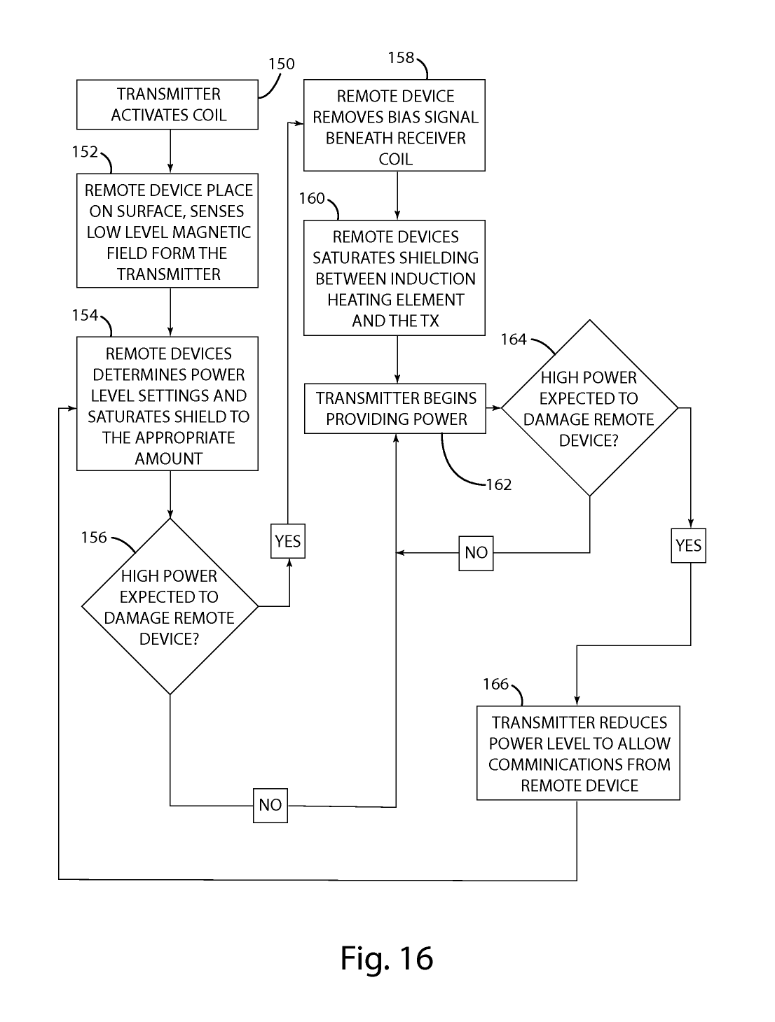

The portable heating device 50 can therefore generate a first flux window proximate the heating element 56 and a second flux window proximate the secondary coil 58. For example, a first plurality of electromagnets 54 can facilitate wireless power transfer through the shielding layer 34 and a second plurality of electromagnets 55 can facilitate communications through the shielding layer 34. A flow chart illustrating this feature is shown in FIG. 16. At step 150, the primary coil array 32 is energized, optionally in response to manual activation by a user. At step 152, the portable heating device 50 is placed on the power transfer surface. During this step, the secondary coil 58 detects a low-level magnetic field through the shielding layer 34. At step 154, the portable heating device 50, and in particular the second plurality of electromagnets 55, saturates the shielding layer 34 between the primary coil 32 and the secondary coil 58. During this step, the portable heating device 50 communicates power requirements for the heating element 56 through the locally saturated shielding layer 34, optionally using both of the primary coil 32 and the secondary coil 58. The wireless power supply 30 operates in a low power mode during this initial communication sequence to avoid damaging sensitive components of the portable heating device 50. At step 156, the portable heating device 50 determines if the expected power exceeds the capacity of the secondary circuit 60. If so, the second plurality of electromagnets 55 lessen their magnetic field strength at step 158. If the expected power does not exceed the capacity of the secondary circuit 60, the magnetic field strength of the second plurality of electromagnets 55 remains unchanged. At step 160, the first plurality of electromagnets 54 saturate the shielding layer 34. The wireless power supply 30 transfers power at step 162 according to the power needs of the heating element 56. The wireless power supply 30 can operate in a high power mode at step 162 to enhance power transfer to the heating element 56. At decision step 164, if a predetermined period has lapsed, the wireless power supply 30 will reduce its power output to the low power mode to allow communications from the portable heating device 50 at step 166. The second plurality of electromagnets then saturate the shielding layer 34 at step 152 to facilitate communications between the primary and secondary coils 32, 58 without damaging or overloading the secondary circuit 60. This process repeats itself until the portable heating device 50 is removed from the power transfer surface or until the primary coil array 32 is manual deactivated.

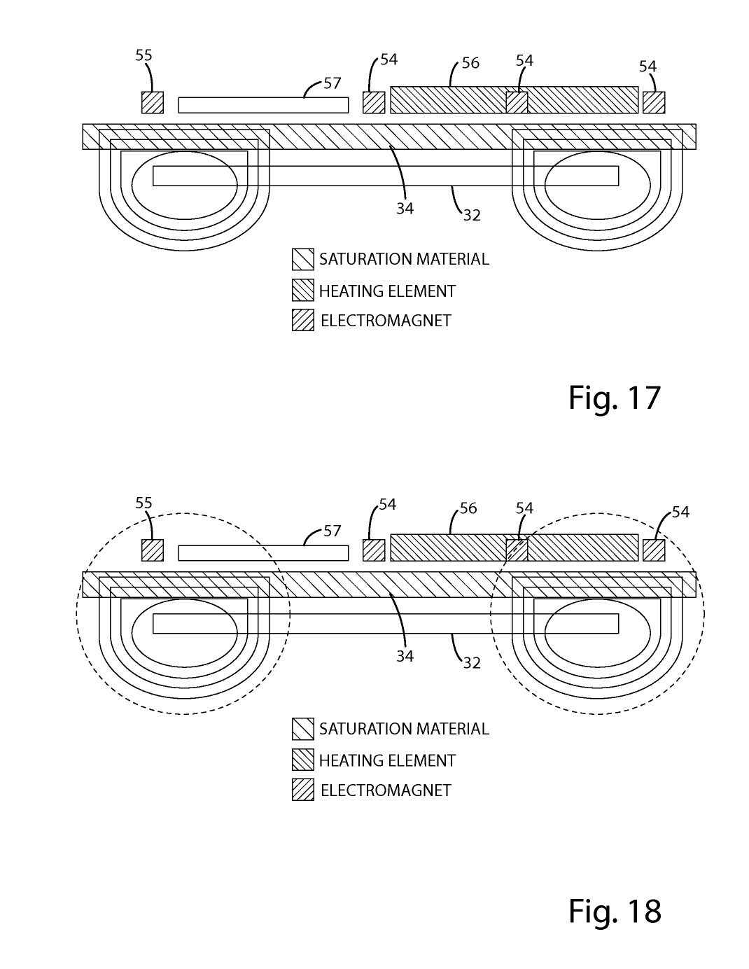

As noted above in connection with step 152, a portion of the electromagnetic flux from the primary coil array 32 penetrates the shielding layer 34 when in a non-saturated state. This is perhaps best shown in FIGS. 17-18, which illustrate the presence of magnetic field lines through the shielding layer 34. Thus, in the non-saturated state, a weak electromagnetic coupling is possible through the shielding layer 34. This weak electromagnetic coupling can be utilized to detect (on the secondary side) the presence of a suitable electromagnetic flux from the primary coil array 32 without exposing sensitive components of the portable heating device 50 to undesirably large amounts of power. The above process is therefore a safeguard for sensitive components of the portable heating device 50. The above process can also be utilized to facilitate communications between an RF transceiver associated with the wireless power supply 30 and an RF transceiver associated with the portable heating device 50. In addition, this process can be combined with the processes described above in connection with FIGS. 9 and 11 for cordless irons, and as well as with portable devices that lack a heating element, including laptop computers, personal digital assistants, tablet computers, mobile telephones and e-book readers for example. In portable devices that lack a heating element, the portable device can instead include an additional secondary coil for enhanced power transfer to the portable device.

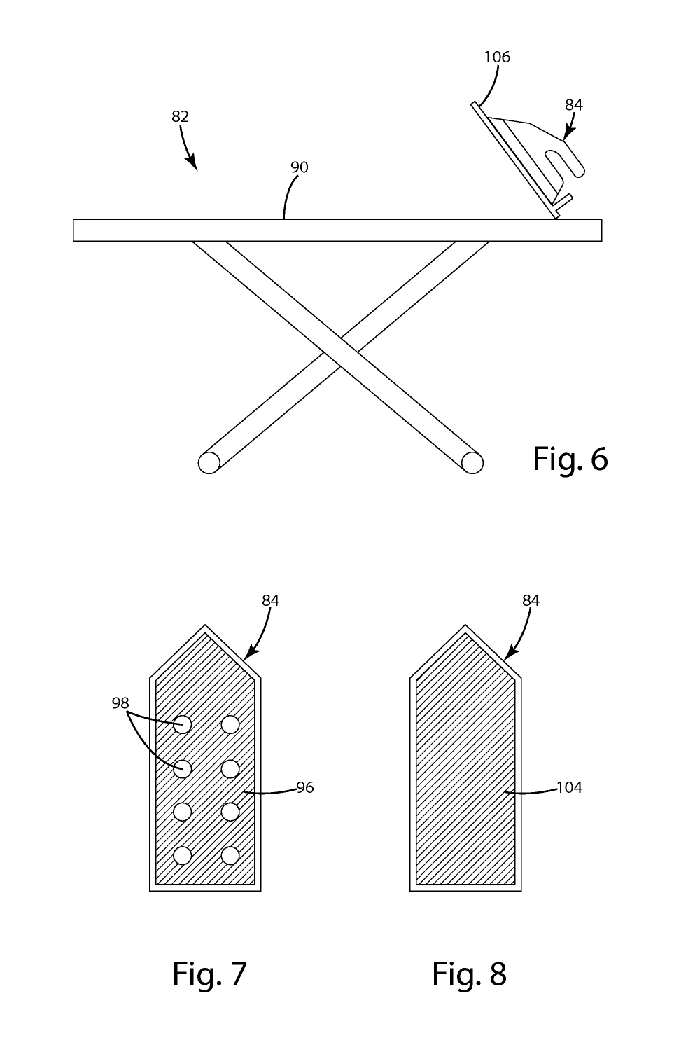

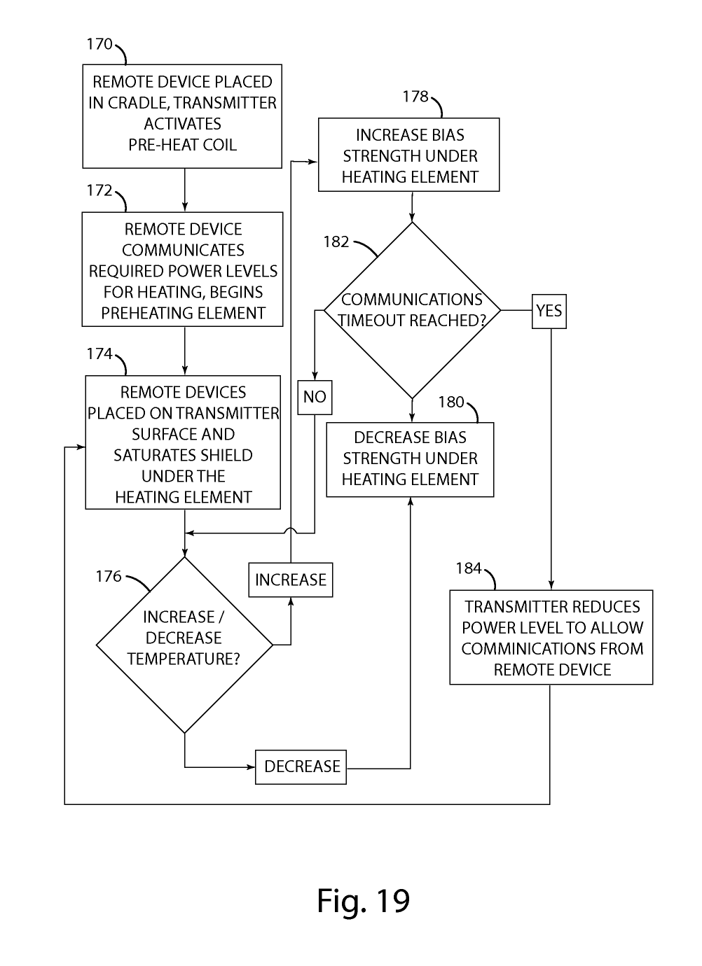

In another embodiment as shown in FIG. 19, a portable heating device 50 can be pre-heated while maintaining sufficient shielding along select portions of the heating device 50. In this embodiment, the portable heating device 50 is placed in a charging cradle 106 at step 170 as generally shown in FIG. 6. The presence of the portable heating device 50 in the charging cradle 106 can be confirmed using a pressure switch or other sensor. In response to the detected presence of the portable heating device 50, a preheating coil contained within charging cradle 106 is energized. At step 172, the portable heating device 50 attempts to establish a communication link with the wireless power supply 30. During this step, and while the portable heating device remains on the charging cradle 106, the portable heating device 50 communicates power requirements for the heating element 56 to the wireless power supply 30. At step 174, the portable heating device 50 is placed on the transmitter surface as generally shown in FIG. 4 and saturates the electromagnets 54 proximate the heating element 56. In what can be described as a closed-loop system, the portable heating device 50 varies the magnetic field strength of the electromagnets 54 to control the temperature of the heating element 56. In particular, the portable heating device 50 determines at step 176 whether the temperature of the heating element should be increased or decreased relative to a recent temperature measurement. If an increase in temperature is desired, the magnetic field strength of the electromagnets 54 increases at step 178. If a decrease in temperature is desired, the magnetic field strength of the electromagnets 54 decreases at step 180. If at decision step 182 a communications timeout is reached, the wireless power supply 30 reduces the power output at step 184 to allow for communications with the portable heating device 50. During this interruption, the portable heating device 50 can communicate updated power demand information to the wireless power supply 30. For example, the portable heating device 50, and in particular the second plurality of electromagnets 55, can briefly saturate the shielding layer 34 between the primary coil 32 and the secondary coil 58. The wireless power supply 30 remains in a low power mode during this communication sequence to avoid damaging sensitive components of the portable heating device 50. The process then resumes at step 174 by returning to a high power mode that is optionally modified in response to data from the portable heating device 50.

Though described above in connection with a portable heating device, embodiments of the wireless power supply system can also be utilized in conjunction with a remote device not having a heating element. Exemplary remote devices include, for example, laptop computers, tablet computers, desktop computers, smartphones, mobile telephones, e-book readers, personal digital assistants, portable gaming systems, console gaming systems, and other electronic devices, whether now known or hereinafter developed. Embodiments can also be used in conjunction with one or more wireless power supplies and/or remote devices set forth in U.S. patent application Ser. No. 13/241,521, entitled “Selectively Controllable Electromagnetic Shielding” by Baarman et al, published as U.S. Patent Application Publication 2012/0112552, the disclosure of which is hereby incorporated by reference in its entirety.

As the term is used herein, a primary coil includes any inductive element adapted to generate an electromagnetic field when driven with a current or voltage. Further by example, a primary coil includes any inductive element adapted to induce eddy currents in a nearby conductive material, and/or adapted to induce an electrical current or voltage in a nearby secondary coil. A secondary coil, as the term is used herein, can include any inductive element adapted to experience a current or voltage when subject to an electromagnetic field. Primary and secondary coils can include, for example, a wound inductive element (e.g., a spirally, helically or toroidally wound inductor), a printed inductive element, and/or an etched inductive element, each including one, less than one, or greater than one “loops” of an electrically conductive material.

The above description is that of current embodiments of the invention. Various alterations and changes can be made without departing from the spirit and broader aspects of the invention as defined in the appended claims, which are to be interpreted in accordance with the principles of patent law including the doctrine of equivalents. This disclosure is presented for illustrative purposes and should not be interpreted as an exhaustive description of all embodiments of the invention or to limit the scope of the claims to the specific elements illustrated or described in connection with these embodiments. For example, and without limitation, any individual element(s) of the described invention may be replaced by alternative elements that provide substantially similar functionality or otherwise provide adequate operation. This includes, for example, presently known alternative elements, such as those that might be currently known to one skilled in the art, and alternative elements that may be developed in the future, such as those that one skilled in the art might, upon development, recognize as an alternative. Further, the disclosed embodiments include a plurality of features that are described in concert and that might cooperatively provide a collection of benefits. The present invention is not limited to only those embodiments that include all of these features or that provide all of the stated benefits, except to the extent otherwise expressly set forth in the issued claims. Any reference to claim elements in the singular, for example, using the articles “a,” “an,” “the” or “said,” is not to be construed as limiting the element to the singular.

1. A wireless power supply system comprising:
a portable heating device including a heating element;
a primary coil adapted to generate an electromagnetic flux; and
an electromagnetic shield interposed between the portable heating device and the primary coil, wherein positioning the portable heating device proximate the electromagnetic shield creates a localized flux window through the electromagnetic shield to increase an electromagnetic coupling between the primary coil and the portable heating device.

2. The wireless power supply system of claim 1 wherein the portable heating device includes a magnetic field source adapted to generate a persistent magnetic field.

3. The wireless power supply system of claim 2 wherein the magnetic field source is operable to reduce a magnetic permeability of the electromagnetic shield to approach the magnetic permeability of ambient space.

4. The wireless power supply system of claim 2 wherein the magnetic field source includes at least one of an electromagnet and a permanent magnet.

5. The wireless power supply system of claim 2 wherein the magnetic field source includes a plurality of magnets disposed radially outward of each other.

6. The wireless power supply system of claim 2 wherein the magnetic field source includes a variable magnetic field strength, wherein the portable heating device is adapted to vary the magnetic field strength to control the electromagnetic coupling through the electromagnetic shield.

7. The wireless power supply system of claim 1 wherein the heating element is adapted to generate heat when subject to the electromagnetic flux.

8. The wireless power supply system of claim 1 wherein the portable heating device further includes a secondary coil electrically coupled to the heating element.

9. The wireless power supply system of claim 1 wherein the electromagnetic shield encompasses a substantial portion of the primary coil to reduce stray electromagnetic flux from the primary coil.

10. The wireless power supply system of claim 1 wherein the electromagnetic shield is adapted to concentrate the electromagnetic flux therein.

11. The wireless power supply system of claim 1 the primary coil and the electromagnetic shield are supported within an ironing board and wherein the portable heating device includes a clothes iron.

12. The wireless power supply system of claim 11 further including a charging cradle adapted to pre-heat the clothes iron.

13. The wireless power supply system of claim 1 further including a power transfer surface for receipt of the portable heating device thereon.

14. The wireless power supply system of claim 14 wherein the portable heating device is slidably positionable along the power transfer surface, and wherein the electromagnetic shield and the primary coil are positioned subjacent the power transfer surface opposite of the portable heating device.

15. A portable heating device comprising:
a heating element; and
a magnetic field source adapted to generate a persistent magnetic field, wherein placement of the magnetic field source proximate an electromagnetic shield increases an electromagnetic coupling through the electromagnetic shield.

16. The portable heating device of claim 15 wherein the heating element includes a ferromagnetic material.

17. The portable heating device of claim 15 further including a secondary coil electrically coupled to the heating element.

18. The portable heating device of claim 15 further including a battery electrically coupled between the secondary coil and the heating element.

19. The portable heating device of claim 15 wherein the magnetic field source includes an electromagnet.

20. The portable heating device of claim 15 wherein the magnetic field source includes a permanent magnet.

21. The portable heating device of claim 15 wherein the magnetic field source includes a plurality of magnets disposed radially outward of each other.

22. The portable heating device of claim 15 wherein the magnetic field source includes a plurality of magnets disposed radially outward of the heating element.

23. The portable heating device of claim 15 wherein the magnetic field source includes a variable magnetic field strength.

24. The portable heating device of claim 23 wherein the portable heating device is adapted to vary the magnetic field strength among a plurality of levels to control the electromagnetic flux through the electromagnetic shield.

25. The portable heating device of claim 15 wherein the portable heating devices comprises one of a clothes iron, a curling iron, a hair straightener, a heating pad, a heated beverage container and an article of cookware.

26. A wireless power supply for use with a portable heating device, the wireless power supply comprising:
a power transfer surface to receive the portable heating device thereon;
a primary coil subjacent the power transfer surface and adapted to generate an electromagnetic flux; and
an electromagnetic shield interposed between the power transfer surface and the primary coil, wherein positioning the portable heating device on the power transfer surface creates a localized flux window through the electromagnetic shield to increase an electromagnetic coupling between the primary coil and the portable heating device.

27. The wireless power supply of claim 26 wherein the electromagnetic shield encompasses a substantial portion of the primary coil.

28. The wireless power supply of claim 26 wherein the electromagnetic shield is adapted to concentrate the electromagnetic flux therein.

29. The wireless power supply of claim 26 the wireless power supply comprises an ironing board.

30. The wireless power supply of claim 26 wherein the wireless power supply includes a charging cradle adapted to pre-heat the portable heating device.

31. The wireless power supply of claim 26 wherein the portable heating device is slidably positionable along the power transfer surface.

32. A method for providing a source of wireless power comprising:
providing a primary coil and an electromagnetic shield;
generating an electromagnetic flux using the primary coil;
positioning a portable heating device proximate a portion of the electromagnetic shield opposite of the primary coil; and
creating a localized flux window in the electromagnetic shield to increase an electromagnetic coupling between the primary coil and the portable heating device through the electromagnetic shield.

33. The method according to claim 32, wherein creating a localized flux window includes decreasing the electromagnetic permeability of the electromagnetic shield at the localized flux window.

34. The method according to claim 32, wherein the portable heating device includes a magnetic field source.

35. The method according to claim 34 wherein the magnetic field source includes a magnetic field strength, the method further including varying the magnetic field strength to control the electromagnetic coupling through the electromagnetic shield.

36. The method according to claim 34 wherein the magnetic field source includes a magnetic field strength, the method further including decreasing the magnetic field strength to decrease the electromagnetic coupling through the electromagnetic shield.

37. The method according to claim 34 wherein the magnetic field source includes a magnetic field strength, the method further including increasing the magnetic field strength to increase the electromagnetic coupling through the electromagnetic shield.

38. The method according to claim 34 further including heating the magnetic field source to decrease the electromagnetic coupling through the electromagnetic shield.

39. The method according to claim 34 further including cooling the magnetic field source to increase the electromagnetic coupling through the electromagnetic shield.

40. The method according to claim 32 further including heating the electromagnetic shield to increase the electromagnetic coupling through the flux window.

41. The method according to claim 32 further including cooling the electromagnetic shield to decrease the electromagnetic coupling through the flux window.
